(19) United States
(12) Patent Application Publication
(10) Pub. No.: US 2025/0291428 A1
(43) Pub. Date: Sep. 18, 2025

(54) KEY DEVICE

(71) Applicant: Chicony Electronics Co., Ltd., New Taipei City (TW)

(72) Inventors: Tao Kuan Chen, New Taipei City (TW); Huei Chen Wong, New Taipei City (TW)

(73) Assignee: Chicony Electronics Co., Ltd., New Taipei City (TW)

(21) Appl. No.: 18/755,698

(22) Filed: Jun. 27, 2024

(30) Foreign Application Priority Data
Mar. 13, 2024 (TW) 113109240

(51) Int. Cl. G06F 3/02; H03K 17/965

(52) U.S. Cl. CPC G06F 3/0202; H03K 17/965

(57) ABSTRACT

A key device includes a housing, a sliding plunger and a cap. The housing includes a key hole. The sliding plunger is movably disposed in the key hole and includes a first positioning portion. The cap includes a second positioning portion corresponding to the first positioning portion, and the cap is detachably disposed on the first positioning portion of the sliding plunger through the second positioning portion.

### CROSS-REFERENCE TO RELATED APPLICATION

This application claims the priority benefit of Taiwan application serial no. 113109240, filed on Mar. 13, 2024. The entirety of the above-mentioned patent application is hereby incorporated by reference herein and made a part of this specification.

### BACKGROUND

### Technical Field

The disclosure relates to a key device, and in particular relates to a key device whose cap is detachable and may be properly installed.

### Description of Related Art

Currently, it is a very common input method for users to input information through keystrokes. When the caps of the keys are worn, how to facilitate the user to replace them by themselves, or to provide the user with the possibility of replacing the caps of his preference, is a research direction in this field.

### SUMMARY

A key device whose cap is detachable and may be properly installed is provided in the disclosure.

A key device of the disclosure includes a housing, a sliding plunger, and a cap. The housing includes a key hole. The sliding plunger is movably disposed in the key hole and includes a first positioning portion. The cap includes a second positioning portion corresponding to the first positioning portion, and the cap is detachably disposed on the first positioning portion of the sliding plunger through the second positioning portion.

In an embodiment of the disclosure, one of the first positioning portion and the second positioning portion includes a protruding portion extending along a first axial direction and a second axial direction perpendicular to each other, another one of the first positioning portion and the second positioning portion includes a recessed portion extending along the first axial direction and the second axial direction, and the protruding portion is detachably engaged with the recessed portion.

In an embodiment of the disclosure, the key device further includes a mechanical switch, and the mechanical switch includes the sliding plunger.

In an embodiment of the disclosure, the key device further includes an elastic body located in the key hole and below the sliding plunger for abutting against the sliding plunger.

In an embodiment of the disclosure, the cap includes a third positioning portion, the elastic body includes a fourth positioning portion corresponding to the third positioning portion, and the third positioning portion and the fourth positioning portion engage with each other to fix the relative position of the elastic body and the cap.

In an embodiment of the disclosure, the sliding plunger includes multiple symmetrically distributed guide ribs.

In an embodiment of the disclosure, the housing includes a side wall, the side wall surrounds the key hole, the side wall includes an upper stop surface, the sliding plunger includes a first limiting portion, and the upper stop surface is located above the first limiting portion to limit the upward movement range of the first limiting portion.

In one embodiment of the disclosure, the sliding plunger includes a buffer component. The first limiting portion includes a top surface facing the cap and the upper stop surface and a bottom surface facing away from the cap. The buffer component protrudes from the top surface and the bottom surface, and the portion of the buffer component that protrudes from the top surface is used to abut against the upper stop surface.

In an embodiment of the disclosure, the side wall includes a lower stop surface, the sliding plunger includes a second limiting portion, and the lower stop surface is located below the second limiting portion to limit the downward movement range of the second limiting portion.

In an embodiment of the disclosure, the side wall includes an elastic arm, and the second limiting portion is a hook located on the elastic arm.

In one embodiment of the disclosure, a range surrounded by a projection of the sliding plunger onto a cap top surface of the cap is greater than 70% of a size of the cap top surface.

Based on the above, the sliding plunger of the key device of the disclosure is movably disposed in the key hole of the housing, and the cap is detachably disposed on the first positioning portion of the sliding plunger through the second positioning portion to be fixed to the sliding plunger. The cap of the key device of the disclosure is detachable to facilitate replacement, and the cap may be properly installed on the sliding plunger through the alignment of the first positioning portion and the second positioning portion, thereby providing stable pressing sensation.

### BRIEF DESCRIPTION OF THE DRAWINGS

FIG. 1 is a schematic diagram of the appearance of a key device according to an embodiment of the disclosure.

FIG. 2 and FIG. 3 are exploded schematic diagrams of the key device in FIG. 1 from different perspectives.

FIG. 4 is a cross-sectional schematic diagram along line A-A in FIG. 1.

FIG. 5 is an exploded diagram of FIG. 4.

FIG. 6 is a cross-sectional schematic diagram along line B-B in FIG. 1.

FIG. 7 is a bottom schematic diagram of the key cap module of the key device of FIG. 1.

FIG. 8 and FIG. 9 are schematic diagrams from different perspectives of the key cap module of a key device moving upward according to another embodiment of the disclosure.

FIG. 10 is a cross-sectional schematic diagram of a key device according to another embodiment of the disclosure.

FIG. 11 and FIG. 12 are schematic diagrams of the sliding plunger of the key device in FIG. 10 from different perspectives.

FIG. 13 is an exploded schematic diagram of the sliding plunger of FIG. 11.

FIG. 14 is a cross-sectional schematic diagram of a key device according to another embodiment of the disclosure.

FIG. 15 and FIG. 16 are schematic diagrams of the key cap module of the key device of FIG. 14 from different perspectives.

### DETAILED DESCRIPTION OF DISCLOSED EMBODIMENTS

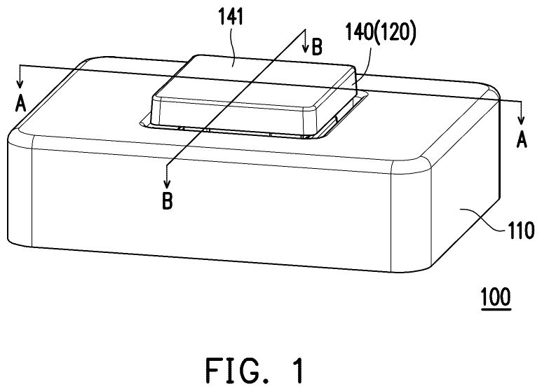

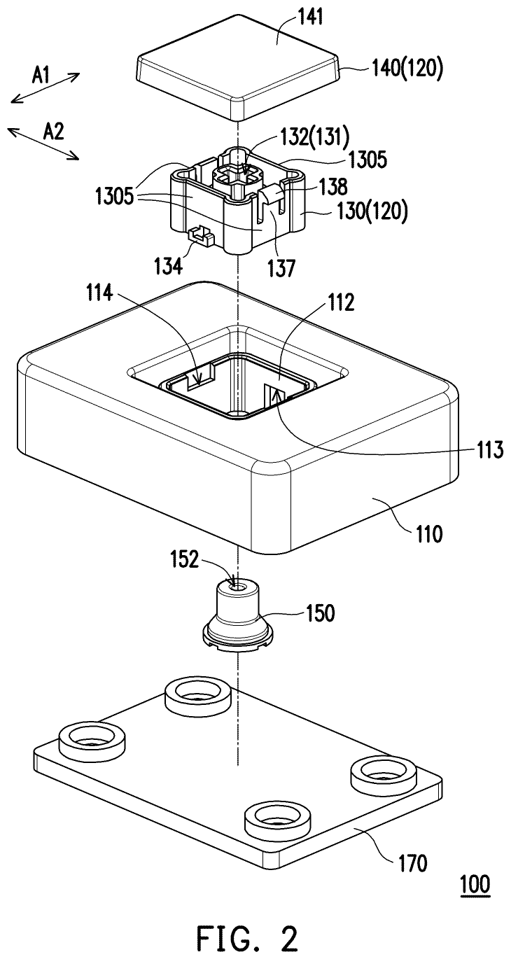

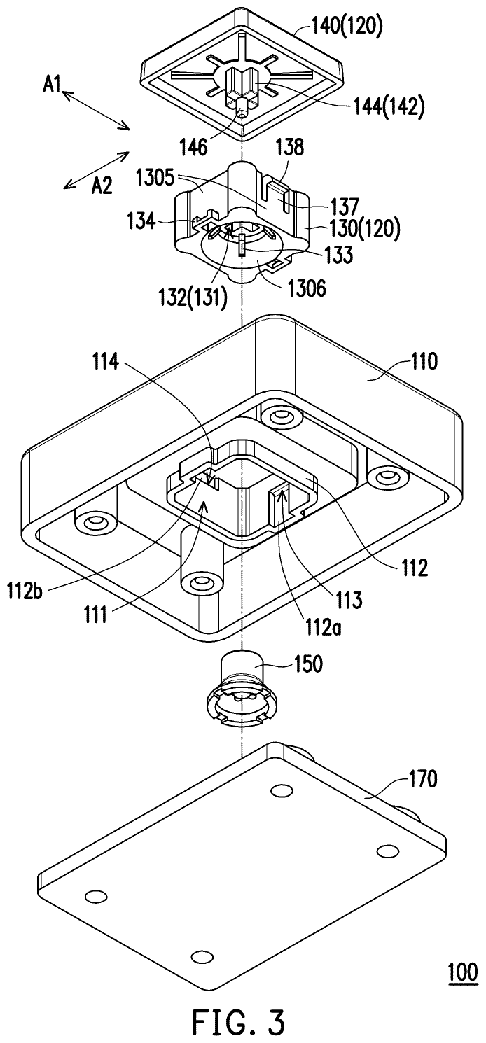

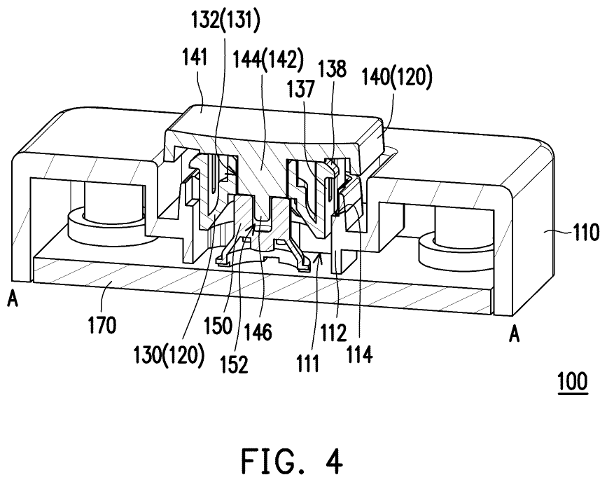

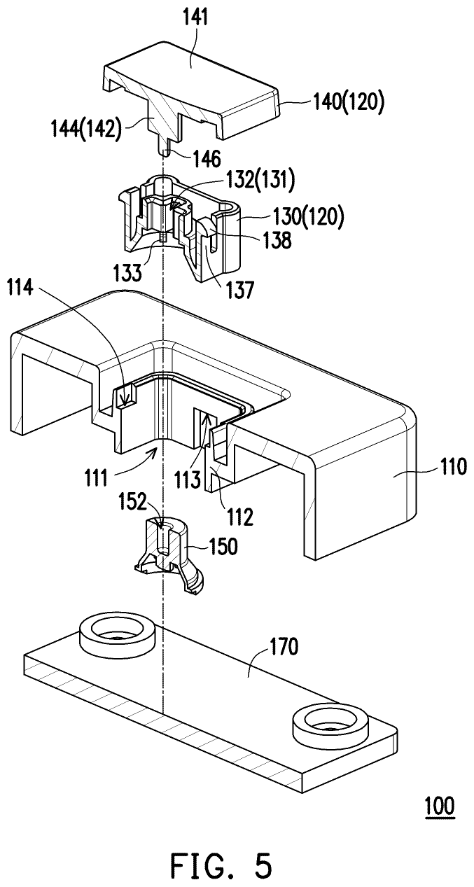

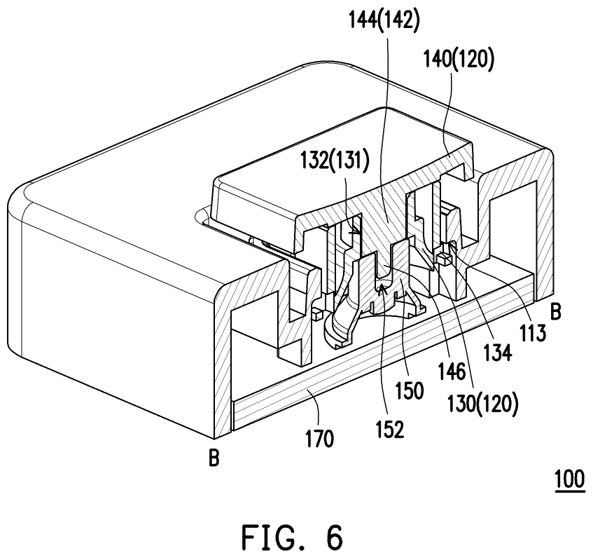

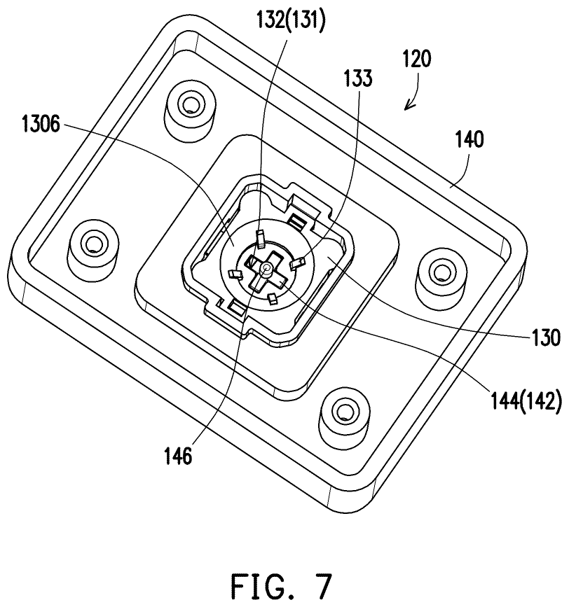

FIG. 1 is a schematic diagram of the appearance of a key device according to an embodiment of the disclosure. FIG. 2 and FIG. 3 are exploded schematic diagrams of the key device in FIG. 1 from different perspectives. FIG. 4 is a cross-sectional schematic diagram along line A-A in FIG. 1. FIG. 5 is an exploded diagram of FIG. 4. FIG. 6 is a cross-sectional schematic diagram along line B-B in FIG. 1. FIG. 7 is a bottom schematic diagram of the key cap module of the key device of FIG. 1.

Referring to FIG. 1 to FIG. 7, the key device 100 of this embodiment includes a housing 110 and a key cap module 120. As shown in FIG. 2 and FIG. 3, the housing 110 includes a side wall 112 and a key hole 111 surrounded by the side wall 112. In this embodiment, the housing 110 is a housing with a single key as an example. The side wall 112 is, for example, an annular inner wall inside the housing 110 that surrounds the key hole 111. However, the position of the side wall 112 is not limited thereto. In other embodiments, the key device 100 may also be a keyboard, so that the housing 110 has multiple key holes 111 and corresponding side walls 112.

The key cap module 120 includes a sliding plunger 130 and a cap 140. The sliding plunger 130 and the cap 140 may be combined to form a single, movable unit. The sliding plunger 130 is movably disposed in the key hole 111 and includes a first positioning portion 131. The cap 140 includes a second positioning portion 142 corresponding to the first positioning portion 131. In this embodiment, the second positioning portion 142 protrudes from the center of the bottom surface of the cap 140, and the first positioning portion 131 is located at the center of the sliding plunger 130 and is disposed facing the cap 140. The cap 140 is detachably disposed on the first positioning portion 131 of the sliding plunger 130 through the second positioning portion 142. Since the cap 140 of the key device 100 of this embodiment is detachable, it is very convenient to replace. If the cap 140 is worn or the user has a preferred cap 140, the user may replace it from the front of the key device 100 without disassembling the entire key device 100. In addition, since the cap 140 may be properly installed on the sliding plunger 130 through the alignment of the first positioning portion 131 and the second positioning portion 142, a stable pressing sensation may be provided.

It is worth mentioning that in this embodiment, since the cap 140 of the key device 100 is detachable, the cap 140 may be shared with other key devices. The form of other key devices is not limited to the key device 100 shown in FIG. 1, as long as the other key devices have a first positioning portion 131 that may match with the second positioning portion 142 of the cap 140. Therefore, if multiple different types of key devices are produced, the same cap 140 may be used, thereby saving mold costs.

In addition, since the sliding plunger 130 and the cap 140 of the key device 100 of this embodiment are two separate pieces, they may be made of different materials. Specifically, the sliding plunger 130 may be made of a relatively self-lubricating material to reduce friction generated during sliding. The material of the sliding plunger 130 is, for example, polyoxymethylene (plastic steel, POM), rubber or silicone. Of course, the material of the sliding plunger 130 is not limited thereto.

In addition, since the sliding plunger 130 and the cap 140 are two separate pieces, they may be produced separately and then assembled together, so the size of the sliding plunger 130 is not limited by the manufacturing process of the mold. The size of the sliding plunger 130 may be increased as much as possible without affecting smooth sliding, and is close to the size of the key hole 111 to facilitate the stability of the key cap module 120 during the movement process, thereby improving the input sensation of the user and efficiency.

As shown in FIG. 2, in this implementation, the sliding plunger 130 includes multiple outer walls 1305, and the first positioning portion 131 is located between these outer walls 1305. The number of outer walls 1305 is, for example, four. The outer contours of these outer walls 1305 are generally square in shape corresponding to the cap 140 and are connected in arcs at the four corners. However, the outer contour of the sliding plunger 130 is not limited thereto.

As shown in FIG. 2 and FIG. 3, the size of the sliding plunger 130 is quite close to the size of the key hole 111, and the size of the sliding plunger 130 is only slightly smaller than the size of the cap 140. Such a design allows the cap 140 to be well supported by the larger sliding plunger 130, even if it is pressed at the four corners rather than the center. This ensures that the cap 140 may move straight up and down, reducing the chances of wobbling. Therefore, the stability of the cap 140 when being pressed may be greatly improved, thereby ensuring good input performance.

In this embodiment, a range surrounded by a projection of the sliding plunger 130 onto a cap top surface 141 of the cap 140 is greater than 70% of a size of the cap top surface 141. Of course, the size relationship between the sliding plunger 130 and the cap 140 is not limited thereto.

In addition, as shown in FIG. 2, in this embodiment, one of the first positioning portion 131 and the second positioning portion 142 includes a protruding portion 144 extending along a first axial direction A1 and a second axial direction A2 perpendicular to each other, another one of the first positioning portion 131 and the second positioning portion 142 includes a recessed portion 132 extending along the first axial direction A1 and the second axial direction A2, and the protruding portion 144 is detachably engaged with the recessed portion 132.

Specifically, in this embodiment, the first positioning portion 131 is a cross-shaped hole, and the second positioning portion 142 is a cross-shaped protruding pillar. The first positioning portion 131 and the second positioning portion 142 may be properly positioned with each other through the above design. Of course, in other embodiments, the first positioning portion 131 and the second positioning portion 142 may also be in other shapes, such as triangles, trapezoids, irregular shapes, etc., and the shapes of the first positioning portion 131 and the second positioning portion 142 are not limited thereto.

In addition, in this embodiment, the first positioning portion 131 and the second positioning portion 142 may be tightly combined through a tight fit to prevent the cap 140 from being easily detached. Of course, the first positioning portion 131 and the second positioning portion 142 may also be combined through other methods such as engagement, but not limited thereto.

In this embodiment, the key device 100 further includes an elastic body 150 and a bottom plate component 170. The elastic body 150 is located in the key hole 111, and the elastic body 150 is located above the bottom plate component 170 and below the sliding plunger 130 for abutting against the sliding plunger 130. The elastic body 150 is, for example, a rubber structure. The elastic body 150 is used to lift the cap 140 and the sliding plunger 130 that are pressed and moved downward, so as to assist the cap 150 and the sliding plunger 130 to reset after being pressed. The bottom plate component 170 includes, for example, a bracket and a circuit film. The bottom plate component 170 is only shown schematically, and the form of the bottom plate component 170 is not limited thereto.

As shown in FIG. 4, the cap 140 includes a third positioning portion 146, the elastic body 150 includes a fourth positioning portion 152 corresponding to the third positioning portion 146, and the third positioning portion 146 and the fourth positioning portion 152 engage with each other to fix the relative position of the elastic body 150 and the cap 140. Such a design may ensure that the elastic body 150 corresponds to the center of the cap 140 to prevent the center of the cap 140 and the center of the elastic body 150 from being displaced due to vibration during assembly or during transportation. Such a design may also ensure that the user feels feedback when pressing, and will not have a different sensation when pressing the four corners of the cap 140.

In this embodiment, the third positioning portion 146 is, for example, a pillar, and the fourth positioning portion 152 is, for example, a hole, but not limited thereto. Specifically, in this embodiment, the third positioning portion 146 extends from the second positioning portion 142 toward the direction of the bottom plate component 170. The shape of the third positioning portion 146 is, for example, a cylinder, and the shape of the fourth positioning portion 152 is, for example, a circular hole. However, in other embodiments, the third positioning portion 146 and the fourth positioning portion 152 may also be of other shapes, such as polygonal, etc., for more accurate alignment. In addition, the third positioning portion 146 and the fourth positioning portion 152 may be tightly combined through a tight fit. Of course, the third positioning portion 146 and the fourth positioning portion 152 may also be combined through other methods such as engagement, but not limited thereto.

In addition, as shown in FIG. 3, the sliding plunger 130 has an inner tapered surface 1306 connected to these outer walls 1305, and the inner tapered surface 1306 faces the elastic body 150. As shown in FIG. 7, the sliding plunger 130 includes multiple symmetrically distributed guide ribs 133 located on the side wall of the inner tapered surface 1306 of the sliding plunger 130. The guide ribs 133 are, for example, strip-shaped and the number is, for example, four, but the shape and number of the guide ribs 133 are not limited thereto. As may be seen from FIG. 5, these guide ribs 133 face the elastic body 150, especially the outer surface of the elastic body 150. Since the guide rib 133 protrudes from the inner tapered surface of the sliding plunger 130, during the assembly process of the elastic body 150 and the sliding plunger 130, the guide rib 133 first comes into contact with the outer surface of the elastic body 150, thereby guiding the elastic body 150 to the center of the sliding plunger 130, achieving an automatic guidance effect. In other embodiments, guide ribs may also be provided on the outer surface of the elastic body 150, or may be provided at other positions of the sliding plunger 130 to guide the assembly of the elastic body 150.

As shown in FIG. 3 and FIG. 6, the side wall 112 of the housing 110 includes an upper stop surface 113. Specifically, the side wall 112 is provided with first guide grooves 112a (FIG. 3) on opposite sides. The first guide grooves 112a are connected to the bottom surface of the housing 110, and the first guide grooves 112a have an upper stop surface 113. The sliding plunger 130 includes a first limiting portion 134 formed on one of the outer walls 1305. The first limiting portion 134 is a square protrusion corresponding to the width of the first guide groove 112a. The first limiting portion 134 is slidably disposed in the first guide groove 112a, and the upper stop surface 113 is located above the first limiting portion 134 to limit the upward movement range of the first limiting portion 134.

As shown in FIG. 3 and FIG. 4, the side wall 112 further includes a lower stop surface 114, and the side wall 112 is provided with second guide grooves 112b on two sides other than the two sides where the first guide groove 112a is provided (FIG. 3). The second guide groove 112b is connected to the top surface of the housing 110, and has a lower stop surface 114. The sliding plunger 130 includes a second limiting portion 138 formed on another outer wall 1305. The second limiting portion 138 is, for example, a hook corresponding to the width of the second guide groove 112b. The first limiting portion 134 is slidably disposed in the second guide groove 112b, and the lower stop surface 114 is located below the second limiting portion 138 to limit the downward movement range of the second limiting portion 138.

Therefore, the sliding plunger 130 may slide between the upper stop surface 113 and the lower stop surface 114 of the housing 110 through the first limiting portion 134 and the second limiting portion 138. In this embodiment, the side wall 112 includes an elastic arm 137, and the second limiting portion 138 is a hook located on the elastic arm 137, so that during installation, the second limiting portion 138 may flex and reset along with the elastic arm 137, facilitating assembly and positioning. Of course, the form of the second limiting portion 138 is not limited thereto.

Other forms of key devices 100′, 100a, and 100b are introduced below, and only the main differences are described. Other identical or similar components are not repeated herein.

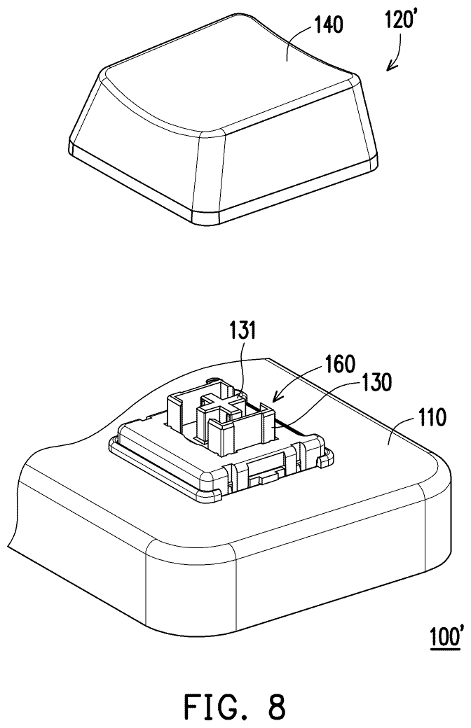

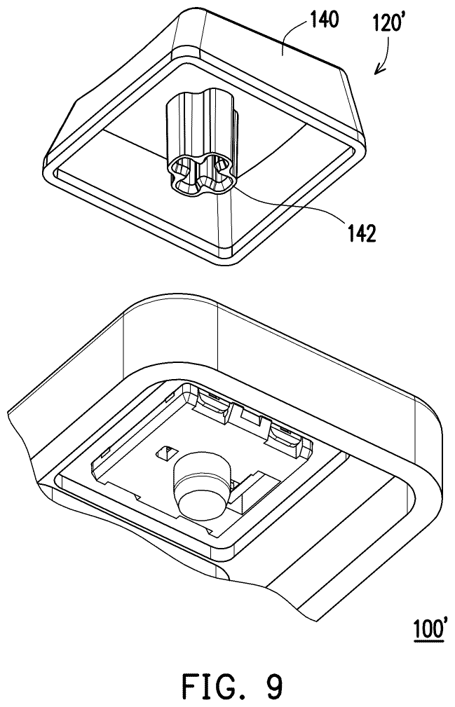

FIG. 8 and FIG. 9 are schematic diagrams from different perspectives of the key cap module of a key device moving upward according to another embodiment of the disclosure. Referring to FIG. 8 and FIG. 9, the main difference between the key device 100′ of this embodiment and the key device 100 of FIG. 1 is that in this embodiment, the key device 100′ is a mechanical key, the key device 100′ further includes a mechanical switch 160, and the mechanical switch 160 includes a sliding plunger 130. That is, the type of the key device in this case may be the key device 100 with the elastic body 150 or the key device 100′ with the mechanical switch 160.

Similarly, the cap 140 of the key cap module 120′ of this embodiment may be properly fixed on the sliding plunger 130 of the mechanical switch 160 through the alignment of the second positioning portion 142 (FIG. 9) and the first positioning portion 131 (FIG. 8) of the sliding plunger 130, providing a stable pressing sensation. In addition, if the cap 140 is worn or the user has a preferred cap 140, the user may also replace it from the front of the key device 100′.

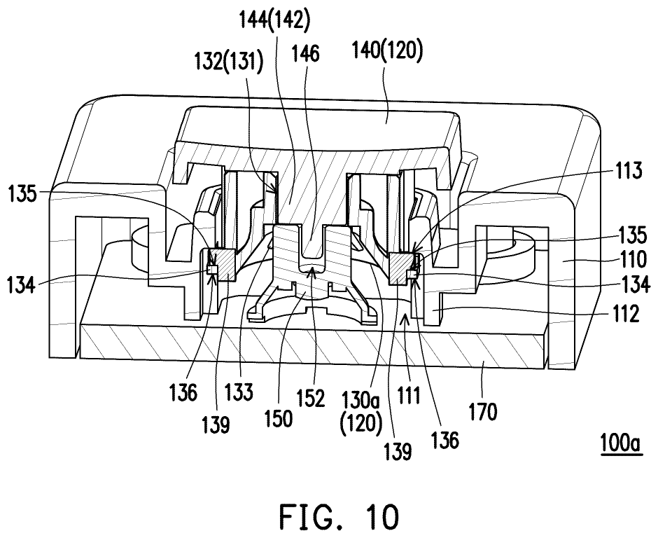

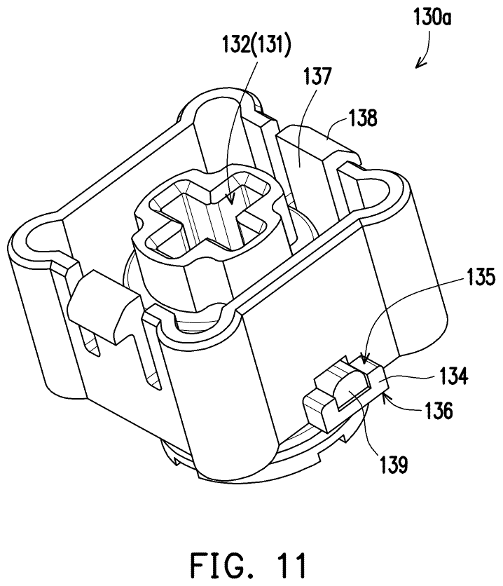

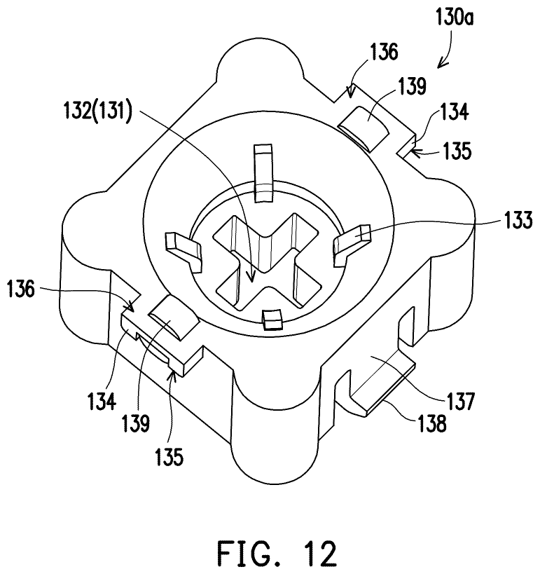

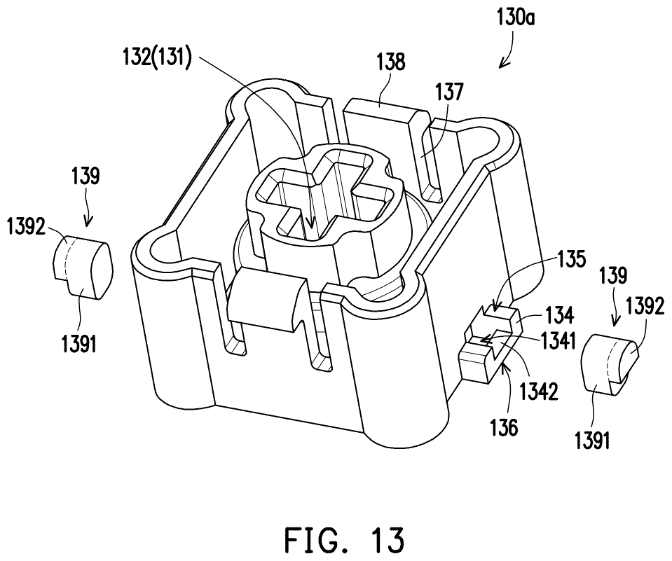

FIG. 10 is a cross-sectional schematic diagram of a key device according to another embodiment of the disclosure. FIG. 11 and FIG. 12 are schematic diagrams of the sliding plunger of the key device in FIG. 10 from different perspectives. FIG. 13 is an exploded schematic diagram of the sliding plunger of FIG. 11.

Referring to FIG. 10 to FIG. 13, the main difference between the key device 100a of this embodiment and the key device 100 of FIG. 1 is that the sliding plunger 130a of this embodiment further includes a buffer component 139. The hardness of the buffer component 139 is less than the hardness of the material of the cap 140 and the sliding plunger 130a. In this embodiment, the buffer component 139 is, for example, rubber or silicone, but the type of the buffer component 139 is not limited thereto.

The first limiting portion 134 includes a top surface 135 facing the cap 140 and the upper stop surface 113 and a bottom surface 136 facing away from the cap 140. The buffer component 139 protrudes from the top surface 135 and the bottom surface 136 of the first limiting portion 134.

The portion of the buffer component 139 that protrudes from the bottom surface 136 is used to first come into contact with the bottom plate component 170 when the cap 140 is pressed, so as to prevent the first limiting portion 134 from directly impacting the bottom plate component 170 and causing greater noise. In addition, in an embodiment not shown, a ring of buffer member may be added at the bottom of the sliding plunger 130a to reduce the probability of the sliding plunger 130a directly impacting the bottom plate component 170.

Similarly, the portion of the buffer component 139 that protrudes from the top surface 135 is used to abut against the upper stop surface 113, and comes into contact with the upper stop surface 113 when the cap 140 rises after being pressed to prevent the first limiting portion 134 from directly impacting the upper stop surface 113 and causing greater noise.

As shown in FIG. 13, in this embodiment, the buffer component 139 and the first limiting portion 134 are two separate pieces, and the buffer component 139 is assembled to the first limiting portion 134. The buffer component 139 penetrates the first limiting portion 134 and protrudes from the top surface 135 and the bottom surface 136.

Specifically, the first limiting portion 134 includes a through hole 1341 and a depressed portion 1342, and the depressed portion 1342 is located next to the through hole 1341. The depressed portion 1342 is depressed from the top surface 135 and is lower than the top surface 135. In this embodiment, the depressed portion 1342 presents, for example, an inner recessed space and a platform lower than the top surface 135 for carrying and accommodating a portion of the buffer component 139. Such a design may enable the buffer component 139 to be disposed on the first limiting portion 134 more firmly and properly. Of course, in other embodiments, the first limiting portion 134 may also omit the design of the depressed portion 1342, which is not limited by the drawings.

The through hole 1341 penetrates through the top surface 135 and the bottom surface 136 of the first limiting portion 134. In addition, the buffer component 139 includes a first portion 1391 and a second portion 1392. The first portion 1391 penetrates through the through hole 1341 and protrudes from the bottom surface 136. The second portion 1392 is located on the depressed portion 1342 and protrudes from the top surface 135.

Such a design may increase the contact area between the buffer component 139 and the first limiting portion 134 to improve the stability of the buffer component 139. Of course, the forms of the first limiting portion 134 and the buffer component 139 are not limited thereto. In other embodiments, the buffer component 139 and the first limiting portion 134 may also be integrally formed, for example, by double injection. However, the relationship between the buffer component 139 and the first limiting portion 134 is not limited to this.

In addition, in one embodiment, the portion of the buffer component 139 that protrudes from the top surface 135 of the first limiting portion 134 and the portion that protrudes from the bottom surface 136 of the first limiting portion 134 may also be two separate pieces respectively assembled on the first limiting portion 134, which are not limited by the drawings.

It is worth mentioning that one of the current conventional noise reduction methods is to provide resistance by pre-pressuring the elastic body under the cap, so that when the user presses down the cap with normal force, the amount of pressing force will not be too large to prevent the structure under the cap from directly impacting the bottom plate component to reduce noise. However, if the elastic body is pre-pressed, the sensation will feel dull when pressing the cap (that is, it will feel more laborious to press), and it may also cause the user to unconsciously increase the amount of pressing force, affecting the smoothness of use. The buffer component 139 of this embodiment is disposed at the first limiting portion 134, and the elastic body 150 is not required to be pre-pressed. Therefore, the user may press the key cap module 120 with normal force, and a good noise reduction effect may be provided.

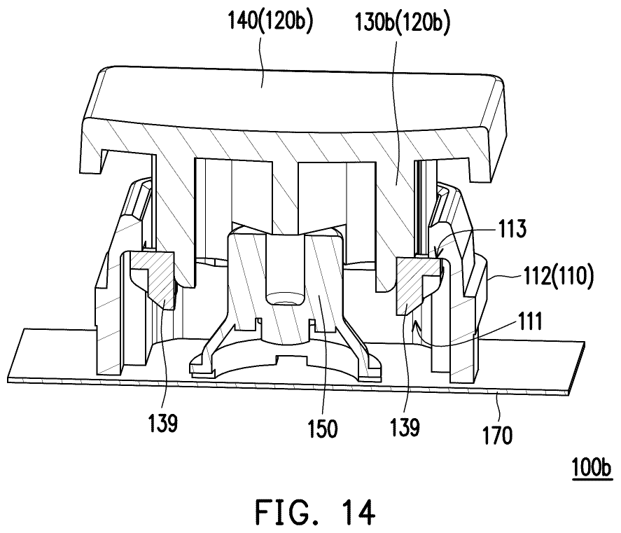

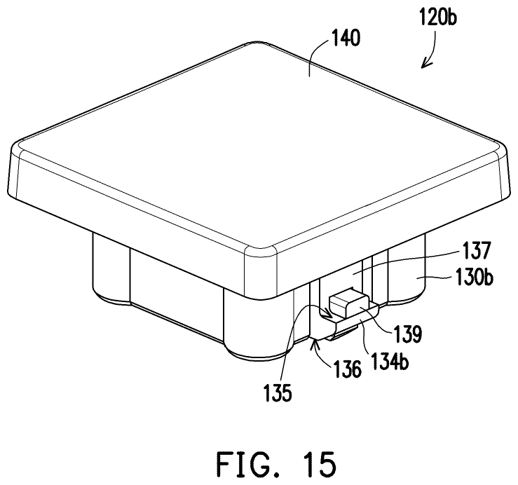

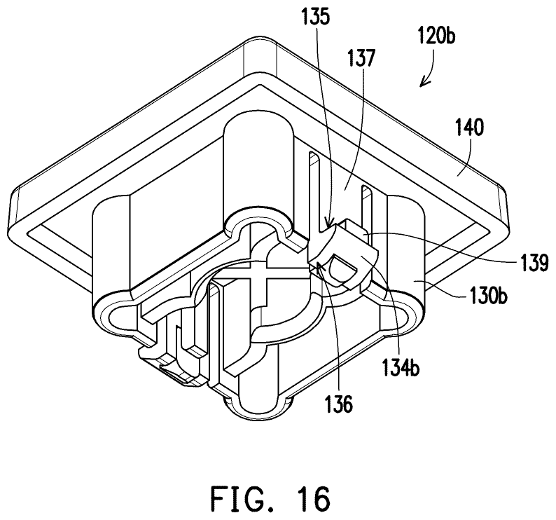

FIG. 14 is a cross-sectional schematic diagram of a key device according to another embodiment of the disclosure. FIG. 15 and FIG. 16 are schematic diagrams of the key cap module of the key device of FIG. 14 from different perspectives. Referring to FIG. 14 to FIG. 16, the main difference between the key device 100b of this embodiment and the key device 100a of FIG. 10 is that the sliding plunger 130b and the cap 140 of the key device 100 of this embodiment are integrated. In addition, in this embodiment, the first limiting portion 134b is provided on the elastic arm 137. Of course, the position of the first limiting portion 134b is not limited thereto.

Similarly, since the sliding plunger 130b of this embodiment includes the buffer component 139 protruding from the top surface 135 and the bottom surface 136 of the first limiting portion 134b, the noise generated when the key cap module 120b is pressed may be effectively reduce, and a more comfortable quality of use may be provided.

To sum up, the sliding plunger of the key device of the disclosure is movably disposed in the key hole of the housing, and the cap is detachably disposed on the first positioning portion of the sliding plunger through the second positioning portion to be fixed to the sliding plunger. The cap of the key device of the disclosure is detachable to facilitate replacement, and the cap may be properly installed on the sliding plunger through the alignment of the first positioning portion and the second positioning portion, thereby providing stable pressing sensation. In addition, the sliding plunger of the key cap module of the key device of the disclosure is provided with a buffer component. The buffer component protrudes from the top surface and the bottom surface of the first limiting portion, which may effectively prevent the first limiting portion from directly impacting other elements when the key cap module is pressed, and has the function of reducing noise, thereby improving the comfort of use.

What is claimed is:

1. A key device, comprising:
a housing, comprising a key hole;
a sliding plunger, movably disposed in the key hole and comprises a first positioning portion; and
a cap, comprises a second positioning portion corresponding to the first positioning portion, wherein the cap is detachably disposed on the first positioning portion of the sliding plunger through the second positioning portion.

2. The key device according to claim 1, wherein one of the first positioning portion and the second positioning portion comprises a protruding portion extending along a first axial direction and a second axial direction perpendicular to each other, another one of the first positioning portion and the second positioning portion comprises a recessed portion extending along the first axial direction and the second axial direction, and the protruding portion is detachably engaged with the recessed portion.

3. The key device according to claim 1, further comprising a mechanical switch, the mechanical switch comprising the sliding plunger.

4. The key device according to claim 1, further comprising an elastic body located in the key hole and below the sliding plunger for abutting against the sliding plunger.

5. The key device according to claim 4, wherein the cap comprises a third positioning portion, the elastic body comprises a fourth positioning portion corresponding to the third positioning portion, and the third positioning portion and the fourth positioning portion engage with each other to fix a relative position of the elastic body and the cap.

6. The key device according to claim 1, wherein the sliding plunger comprises a plurality of symmetrically distributed guide ribs.

7. The key device according to claim 1, wherein the housing comprises a side wall, the side wall surrounds the key hole, the side wall comprises an upper stop surface, the sliding plunger comprises a first limiting portion, and the upper stop surface is located above the first limiting portion to limit an upward movement range of the first limiting portion.

8. The key device according to claim 7, wherein the sliding plunger comprises a buffer component, the first limiting portion comprises a top surface facing the cap and the upper stop surface and a bottom surface facing away from the cap, the buffer component protrudes from the top surface and the bottom surface, and a portion of the buffer component that protrudes from the top surface is used to abut against the upper stop surface.

9. The key device according to claim 7, wherein the side wall comprises a lower stop surface, the sliding plunger comprises a second limiting portion, and the lower stop surface is located below the second limiting portion to limit a downward movement range of the second limiting portion.

10. The key device according to claim 9, wherein the side wall comprises an elastic arm, and the second limiting portion is a hook located on the elastic arm.

11. The key device according to claim 1, wherein a range surrounded by a projection of the sliding plunger onto a cap top surface of the cap is greater than 70% of a size of the cap top surface.
